(19) United States
(12) Patent Application Publication
(10) Pub. No.: US 2019/0119101 A1
(43) Pub. Date: Apr. 25, 2019

(54) AMORPHOUS THIN METAL FILM

(71) Applicants: HEWLETT-PACKARD DEVELOPMENT COMPANY, L.P., Houston, TX (US); The State of Oregon State Board of Higher Education on behalf of Oregon State University, CorvalliS, OR (US)

(72) Inventors: James Elmer Abbott, Jr., Corvallis, OR (US); John M McGlone, Corvallis, OR (US); Kristopher Olsen, Corvallis, OR (US); Roberto A Pugliese, Tangent, OR (US); Greg Scott Long, Corvallis, OR (US); John Wager, Corvallis, OR (US); Douglas A Keszler, Corvallis, OR (US); T. Stafford Johnson, Corvallis, OR (US); William F Stickel, Corvallis, OR (US)

(73) Assignees: HEWLETT-PACKARD DEVELOPMENT COMPANY, L.P., Houston, TX (US); The State of Oregon State Board of Higher Education on behalf of Oregon State University, Corvallis, OR (US)

(21) Appl. No.: 16/068,261

(22) PCT Filed: Jun. 24, 2016
(86) PCT No.: PCT/US2016/039189

§ 371 Date: Jul. 5, 2018

(51) Int. Cl. B81B 7/00; C23C 14/18; C23C 8/10; C23C 14/34; B81C 1/00; B41J 2/14

(52) U.S. Cl. CPC B81B 7/0025; C23C 14/18; C23C 8/10; C23C 14/34; B81B 2201/052; B41J 2/14129; B81C 2201/0181; B81C 2201/0178; B81C 1/00809

(57) ABSTRACT

An amorphous thin film stack can include a first layer including a combination metals or metalloids including: 5 at % to in 90 at % of a metalloid; 5 at % to 90 at % of a first metal and a second metal independently selected from titanium, vanadium, chromium, iron, cobalt, nickel, niobium, molybdenum, ruthenium, rhodium, palladium, tantalum, tungsten, osmium, iridium, or platinum. The three elements may account for at least 70 at % of the amorphous thin film stack. The stack can further include a second layer formed on a surface of the first layer. The second layer can be an oxide layer, a nitride layer, or a combination thereof. The second layer can have an average thickness of 10 angstroms to 200 microns and a thickness variance no greater than 15% of the average thickness of the second layer.

### BACKGROUND

Thin metal films can be used in various applications such as electronic semiconductor devices, optical coatings, and printing technologies. As such, once deposited, thin metal films can be subjected to harsh environments. For example, such thin films may be subjected to high heat, corrosive chemicals, etc.

In a typical inkjet printing system, an inkjet printhead ejects fluid (e.g., ink) droplets through a plurality of nozzles toward a print medium, such as a sheet of paper or other substrate, to print an image onto the print medium. The nozzles are generally arranged in one or more arrays or patterns, such that properly sequenced ejection of ink from the nozzles causes characters or other images to be printed on the print medium as the printhead and the print medium are moved relative to one another.

Because the ejection process is repeated thousands of times per second during printing, collapsing vapor bubbles can contribute to an adverse effect of damaging the heating element. The repeated collapsing of the vapor bubbles leads to cavitation damage to the surface material that coats the heating element. Each of these collapse events can thus contribute to ablation of the coating material. Once ink penetrates the surface material coating the heating element and contacts the hot, high voltage resistor surface, rapid corrosion and physical destruction of the resistor soon follows, rendering the heating element ineffective. There are also other examples of systems, outside of the inkjet arts, where structures may undergo contact with harsh environments. As such, research and development continues in the area of thin metal films used in various applications that can provide improved performance.

### BRIEF DESCRIPTION OF THE DRAWINGS

Additional features and advantages of the present disclosure will be apparent from the detailed description which follows, taken in conjunction with the accompanying drawings, which together illustrate, by way of example, features of the present technology.

FIG. 1 shows an example schematic cross-sectional view of a distribution of elements of a three component amorphous thin metal film in accordance with the present disclosure;

FIG. 2 shows an example of a lattice structure of a three component amorphous thin metal film in accordance with the present disclosure;

FIG. 3 shows an example schematic cross-sectional view of a distribution of elements of a four component amorphous thin metal film in accordance with the present disclosure;

FIG. 4 shows an example of a lattice structure of a four component amorphous thin metal film in accordance with the present disclosure;

FIG. 5 is an example cross-section schematic view of an amorphous thin film stack in accordance with the present disclosure;

FIG. 6 is an example cross-sectional schematic view of a portion of a thermal inkjet printhead with a thin film stack in accordance with the present disclosure;

FIG. 7 depicts an example oxide layer formation rate of two amorphous thin metal films at different oxidation temperatures in accordance with the present disclosure;

FIG. 8 depicts an example of stacked x-ray diffraction patterns of an amorphous thin metal film at different temperatures in accordance with the present disclosure.

Reference will now be made to specific examples illustrated, and specific language will be used herein to describe the same. It will nevertheless be understood that no limitation of the scope of the present disclosure is thereby intended.

### DETAILED DESCRIPTION

Amorphous thin metal films that can be stable having robust chemical, thermal, and mechanical properties are disclosed. As many thin metal films have a crystalline structure that possess grain boundaries and a rough surface, there are certain films disclosed herein that can be more robust and which are amorphous in character. Grain boundaries and rough surfaces can hamper the thin metal film's chemical, thermal, and mechanical properties. Thus, in accordance with the present disclosure, thin metal films can be made from a multi-component system, such as a three or four (or even five or six) component system, providing a stable and amorphous structure having superior chemical, thermal, and mechanical properties.

In accordance with this, the present disclosure is drawn to an amorphous thin film stack including a combination of a plurality of components or elements. It is noted that when discussing an amorphous thin film stack, a method of manufacturing an amorphous thin film stack, or a microelectromechanical system (MEMS) device, each of these discussions can be considered applicable to each of these examples, whether or not they are explicitly discussed in the context of that specific example. Thus, for example, in discussing a metalloid for an amorphous thin metal film in the stack, such a metalloid can also be used in a method of manufacturing an amorphous thin metal film in a stack or a MEMS device, and vice versa.

As such, with the present discussion in mind, an amorphous thin film stack can include a first layer of an amorphous thin metal film or alloy including: 5 at % (or “atomic %”) to 90 at % of a metalloid that can be carbon, silicon, or boron; 5 at % to 90 at % of a first metal that can be titanium, vanadium, chromium, iron, cobalt, nickel, niobium, molybdenum, ruthenium, rhodium, palladium, tantalum, tungsten, osmium, iridium, or platinum; and 5 at % to 90 at % of a second metal that can be titanium, vanadium, chromium, iron, cobalt, nickel, niobium, molybdenum, ruthenium, rhodium, palladium, tantalum, tungsten, osmium, iridium, or platinum. The second metal is different than the first metal.

Generally, the combination of the metalloid, the first metal, and the second metal of the amorphous thin metal film (or first layer of the stack) can account for at least 70 at % of the components in the film, or alternatively, at least 80 at % of the first layer of the amorphous thin metal film. In one example, two of the three elements can account for at least 70 at % of the first layer of the amorphous thin metal film, or at least 80 at % of the first layer of the amorphous thin metal film. This range of metalloid, first metal, and second metal, can likewise be independently modified at the lower end to 10 at %, or 20 at %, and/or at the upper end to 40 at %, 50 at %, 70 at %, or 80 at %. Furthermore, in one example, the combination of the metalloid, the first metal, and the second metal can account for at least 80 at %, at least 90 at %, or even 100 at % of amorphous thin metal film. In one example, the amorphous thin metal film can further include from 5 at % to 80 at % of a third metal, wherein the third metal is titanium, vanadium, chromium, iron, cobalt, nickel, niobium, molybdenum, ruthenium, rhodium, palladium, tantalum, tungsten, osmium, iridium, or platinum, and wherein the first metal, the second metal, and the third metal are different metals, and wherein the metalloid, the first metal, the second metal, and the third metal account for at least 70 at % of the first layer of the amorphous thin metal film.

The present mixture of elements in the amorphous thin metal film can be mixed in a manner and in quantities such that the mixture is homogenous. Additionally, the mixture can be sintered and further applied to a suitable substrate using deposition techniques. Generally, the resulting thin metal film can be amorphous. By using three or more components (or four or more components, or five or more components, etc.) in high enough concentrations, a “confusion” of sizes and properties disfavors the formation of lattice structures that are more typical in single component or even two component systems. Selecting components with suitable size differentials can contribute to minimizing crystallization of the structure. For example, the amorphous thin metal film can have an atomic dispersity of at least 12% between two of the plurality of elements. In another aspect, the amorphous thin metal film can have an atomic dispersity of at least 12% between all of the plurality of elements, e.g., metalloid, first metal, and cerium. As used herein, “atomic dispersity” refers to the difference in size between the radii of two atoms. In one example, the atomic dispersity can be at least 15%, and in one aspect, can be at least 20%. The atomic dispersity between components can contribute to the exceptional properties of the present films, including thermal stability, oxidative stability, chemical stability, and surface roughness, which are not achieved by typical thin metal films. Oxidative stability can be measured by the amorphous thin metal film's oxidation temperature and/or oxide growth rate as discussed herein.

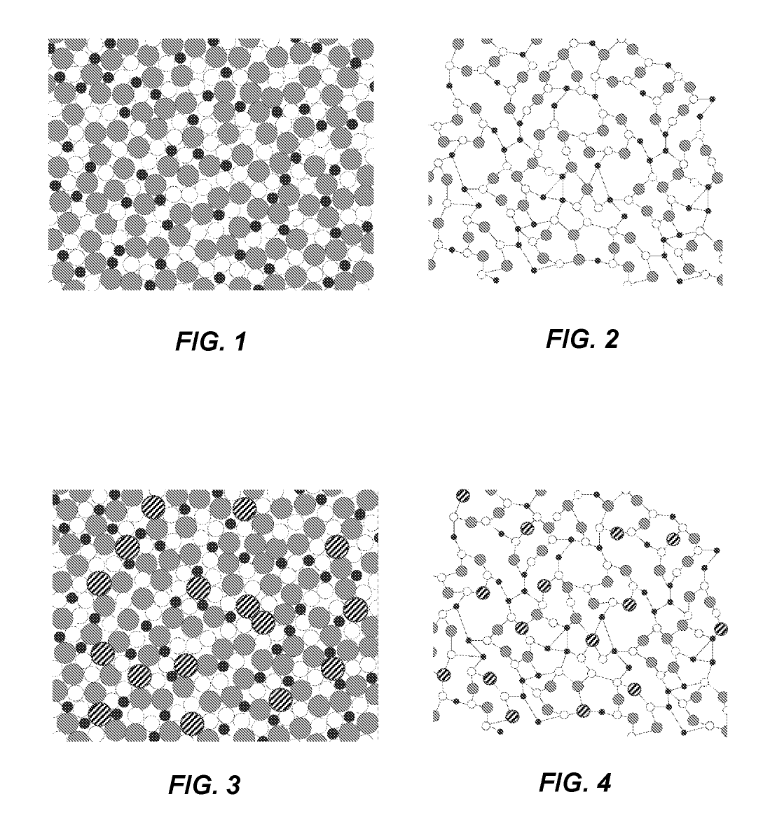

Turning now to FIG. 1, the amorphous thin metal films can have a distribution of components with an atomic dispersity as represented in FIG. 1. Notably, the first layer of the present thin metal films can be generally amorphous with a smooth, grain-free structure. Likewise, the lattice structure of the amorphous thin metal films can be represented by FIG. 2 as compared to typical films with a more crystalline lattice structure having grain boundaries.

As shown in FIG. 3, the amorphous thin metal films can include a third metal (for a total of four components), and these components can have a component distribution with an atomic dispersity as shown therein. As previously mentioned, the thin metal films can be generally amorphous with a smooth, grain-free structure. Thus, where the first layer of the thin metal film includes a third metal, the lattice structure can be represented by FIG. 4. Additional metals can likewise be included, such as a fourth (different) metal and/or a fifth (different) metal.

As discussed herein, the amorphous thin metal films (which can be the first layer of the amorphous thin film stack) can have acceptable properties including thermal stability, oxidative stability, and surface roughness. In one example, the first layer of the thin metal films can have a root mean square (RMS) roughness of less than 1 nm. In one aspect, the RMS roughness can be less than 0.5 nm. In another aspect, the RMS roughness can be less than 0.1 nm. One method to measure the RMS roughness includes measuring atomic force microscopy (AFM) over a 100 nm by 100 nm area. In other aspects, the AFM can be measured over a 10 nm by 10 nm area, a 50 nm by 50 nm area, or a 1 micron by 1 micron area. Other light scattering techniques can also be used such as x-ray reflectivity or spectroscopic ellipsometry.

In another example, the amorphous thin metal film can have a thermal stability of at least 700° C. In one aspect, the thermal stability can be at least 800° C. In another aspect, the thermal stability can be at least 900° C., or at least 1000° C. As used herein, “thermal stability” refers to the maximum temperature that the amorphous thin metal film can be heated while maintaining an amorphous structure. One method to measure the thermal stability includes sealing the amorphous thin metal film in a quartz tube, heating the tube to a temperature, and using x-ray diffraction to evaluate the atomic structure and degree of atomic ordering.

Depending on the components and the method of manufacture, the amorphous thin metal film can have a wide range of electric resistivity. In one non-limiting example, the electrical resistivity can range from 100 μΩ·cm to 2000 μΩ·cm.

Generally, the amorphous thin metal film can have a positive heat of mixing. As discussed herein, the present thin metal films generally include a metalloid, a first metal, and a second, where the first metal and second metals can include elements selected from Periodic Table Groups IV, V, VI, VII, VIII, IX, and X (4, 5, 6, 7, 8, 9, and 10).

In some examples, the amorphous thin metal film can also include from 5 at % to 85 at % of a third metal, as mentioned previously (as shown in FIGS. 3 and 4). The third metal can include metals such as titanium, vanadium, chromium, iron, cobalt, nickel, niobium, molybdenum, ruthenium, rhodium, palladium, tantalum, tungsten, osmium, iridium, or platinum. In this example, the third metal can be different than the first metal and the second metal. This range of third metal can likewise be independently modified at the lower end to 10 at %, or 20 at %, and/or at the upper end to 80 at %, or 70 at %. Furthermore, in one example, the metalloid, the first metal, the second metal, and the third metal, when present, can account for at least 70 at %, at least 80 at %, at least 90 at %, or even 100 at % of the amorphous thin metal film.

In another example, the amorphous thin metal films can include a refractory metal selected from the group of titanium, vanadium, chromium, niobium, molybdenum, ruthenium, rhodium, tantalum, tungsten, osmium, and iridium. In one example, the first, second, and/or third metal can be a refractory metal, respectively.

In one aspect, the first and/or second metal can be present in the thin film in an amount ranging from 20 at % to 90 at %. In another aspect, the first and/or second metal can be present in the thin film in an amount ranging from 20 at % to 70 at %. In some examples, the first metal can be present in the thin film in an amount ranging from 10 at % to 50 at % and the second metal can be present in the thin film in an amount ranging from 10 at % to 40 at %.

Additionally, in some examples, the amorphous thin metal films can further include a dopant. In one example, the dopant can include nitrogen, oxygen, and mixtures thereof. The dopant can generally be present in the amorphous thin metal film in an amount ranging from 0.1 at % to 15 at %. In one example, the dopant can be present in an amount ranging from 0.1 at % to 5 at %. Smaller amounts of dopants can also be present, but at such low concentrations, they would typically be considered impurities. Additionally, in one aspect, the amorphous thin metal film can be devoid of aluminum, silver, and gold.

Generally, the amorphous thin metal film can have a thickness ranging from 10 angstroms to 100 microns. In one example, the thickness can be from 10 angstroms to 2 microns. In another example, the amorphous thin metal film can have a thickness ranging from 0.02 microns to 2 microns. In one aspect, the thickness can be from 0.05 microns to 0.5 microns.

The amorphous thin metal film further includes a second layer formed on a surface of the first layer. The second layer can have an average thickness of from 10 angstroms to 200 microns and a thickness variance no greater than 15% of the average thickness of the second layer. Generally, the second layer can be an oxide layer, a nitride layer, or a combination thereof. In some examples, the second layer can be an oxide layer. In some examples, the second layer can be a nitride layer.

In some examples, the second layer can have an average thickness of from 20 angstroms to 100 microns, or from 50 angstroms to 50 microns. Further, in some examples, the thickness variance can be no greater than 12% of the average thickness of the second layer, or no greater than 10% of the average thickness of the second layer.

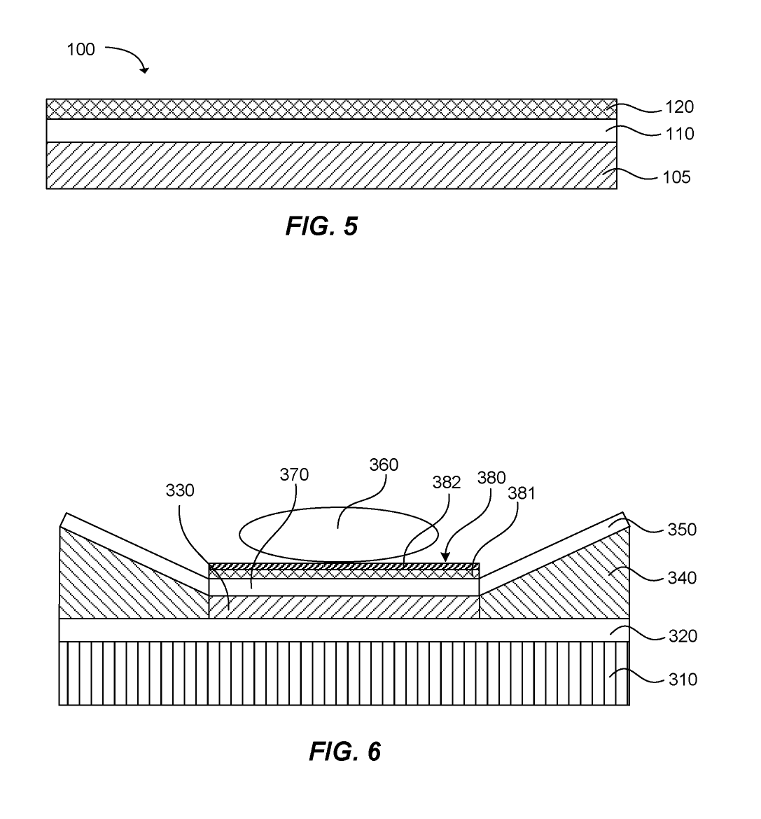

FIG. 5 illustrates an example of an amorphous thin film 100 where the first layer 110 has been applied to a substrate 105, such as a SiO₂ substrate, for example. The second layer 120 can be formed on an upper surface of the first layer.

Turning now to a method of manufacturing an amorphous thin metal film, the method can include depositing a metalloid, a first metal, and second metal to a substrate to form the amorphous thin metal film. The amorphous thin metal film can include 5 at % to 90 at % of the metalloid selected from the group of carbon, silicon, and boron; 5 at % to 90 at % of the first metal selected from the group of titanium, vanadium, chromium, iron, cobalt, nickel, niobium, molybdenum, ruthenium, rhodium, palladium, tantalum, tungsten, osmium, iridium, or platinum; and 5 at % to 90 at % of a the second metal selected from the group of titanium, vanadium, chromium, iron, cobalt, nickel, niobium, molybdenum, ruthenium, rhodium, palladium, tantalum, tungsten, osmium, iridium, or platinum. The first metal and the second metal can be different from one another. Further, the metalloid, the first metal, and the second metal may account for at least 70 at % of the amorphous thin metal film.

In some examples, the method can also include depositing a third metal selected from the group of titanium, vanadium, chromium, iron, cobalt, nickel, niobium, molybdenum, ruthenium, rhodium, palladium, tantalum, tungsten, osmium, iridium, or platinum.

In another example, prior to depositing, the metalloid, the first metal, the second metal, and in some examples the third metal, can be mixed to form a blend that can be subsequently deposited to form the amorphous thin metal film.

Generally, the step of depositing can include sputtering, atomic layer deposition, chemical vapor deposition, electron beam deposition, ion beam deposition, or thermal evaporation. In one example, the depositing can be sputtering. The sputtering can generally be performed at 1 mTorr to 20 mTorr or 5 mTorr to 15 mTorr at a deposition rate of 5 to 10 nm/min with the target approximately 2 inches to 4 inches from a stationary substrate. Other deposition conditions may be used and other deposition rates can be achieved depending on variables such as target size, electrical power used, pressure, sputter gas, target to substrate spacing, and a variety of other deposition system dependent variables. In another aspect, depositing can be performed in the presence of a dopant that is incorporated into the thin film. In another specific aspect, the dopant can be oxygen and/or nitrogen.

A second layer can then be formed on a surface of the amorphous thin metal film to form the amorphous thin film stack. The second layer can have a thickness of from 10 angstroms to 200 microns and a thickness variance no greater than 15% of the average thickness of the second layer. The second layer can be an oxide layer, a nitride layer, or a combination thereof.

The second layer can be formed on the surface of the first layer via a number of suitable methods. Generally, any method that can add energy density in air or other reactive environment can be used. For example, the first layer of the amorphous thin metal film can be placed in a furnace and heated at a temperature of from 200° C. or 300° C. to 1000° C. in an oxygen, nitrogen, or similar environment. In some examples, the second layer can be formed by exposing the amorphous thin metal film (first layer) to an oxygen or nitrogen plasma. In other examples, a rapid thermal processing system can be employed to form the second layer. In yet other examples, solution based chemistry, ozone, lasers, etc. can be used to form the second layer. Notably, the amorphous thin metal films as discussed herein can have acceptable properties related to thermal stability, oxidative stability, chemical stability, and surface roughness for use in hot and harsh environments described herein. As such, the present thin metal films can be used in a number of applications including electronic semiconductor devices, optical coatings, and printing technologies, for example.

In one specific example, the amorphous thin metal film can be used in a MEMS device. The MEMS device can include a substrate, a first layer of an amorphous thin metal film or alloy applied to the substrate, and a second layer formed on a surface of the amorphous thin metal film or alloy. The amorphous thin metal film can include from 5 at % to 90 at % of a metalloid of carbon, silicon, or boron; from 5 at % to 90 at % of a first metal of titanium, vanadium, chromium, iron, cobalt, nickel, niobium, molybdenum, ruthenium, rhodium, palladium, tantalum, tungsten, osmium, iridium, or platinum; and from 5 at % to 90 at % of a second metal of titanium, vanadium, chromium, iron, cobalt, nickel, niobium, molybdenum, ruthenium, rhodium, palladium, tantalum, tungsten, osmium, iridium, or platinum. The first metal and the second metal can be different from one another. The metalloid, the first metal, and the second metal can account for at least 70 at % of the amorphous thin metal protective layer.

The first layer can have any suitable thickness, such as those described above. However, for certain MEMS applications, the first layer can have an average thickness of from 10 angstroms to 2 microns or from 20 angstroms to 1 micron.

The second layer can have an average thickness of 10 angstroms to 200 microns and a thickness variance no greater than 15% of the average thickness of the second layer. The second layer can be an oxide layer, a nitride layer, or a combination thereof.

While the second layer can have any suitable thickness, such as those described herein, for certain MEMS applications, the second layer can have an average thickness from 100 angstroms to 4 microns or from 200 angstroms to 3 microns.

The MEMS applications for which the present amorphous thin metal films can be used are not particularly limited. Non-limiting examples can include accelerometers, microphones, gyroscopes, oscillators, pressure sensors, displays, optical switches, piezoelectrics, ultrasound transducers, energy harvesting, inkjet printing, etc.

In one specific example, the MEMS device can be a thermal inkjet printhead. While the amorphous thin metal film can be used as various components of the thermal inkjet printhead, in one specific example the amorphous thin metal film can be used as an amorphous thin metal protective layer.

An example thermal inkjet printhead stack including an amorphous thin metal film as a metal protective layer is illustrated in FIG. 6. Specifically, a silicon wafer 310 is shown having an electrical insulating layer 320 applied thereto. To the insulating layer can be applied a resistor 330, which can be prepared using any known resistor material known in the thermal inkjet printing arts, such as TaAl, WSiN, TaSiN, TaN, or Ta₂O₅. A suitable average thickness for the resistor can be from 0.02 microns to 0.5 microns or from 0.02 microns to 2 microns, though thicknesses outside of this range can also be used. Furthermore, the resistor, as described, can be doped with any material suitable for achieving desired electrical properties, including, but not limited to, resistivity. The resistor can likewise be in electrical communication with a pair of conductors 340 positioned on either side of the resistor. These conductors can act as electrodes for the resistor. In this example, the conductors are also applied to the insulating layer, though this arrangement is merely exemplary. The conductors can be of any material suitable for use as conductors, but in one example, the conductors can be aluminum, or an alloy of aluminum and copper.

Furthermore, conductor passivation layers 350, which can also be insulating, can be applied to the conductors to prevent contact between the ink 360 and the conductors. A suitable average thickness for the conductors can be from 0.1 micron to 2 microns, and a suitable average thickness for the passivation layers can be from 0.02 micron to 1 micron, though thicknesses outside of this range can also be suitable.

To the resistor 330, a resistor passivation layer 370 can likewise be applied. This film can be relatively thin to relatively thick, e.g., from 50 angstroms to 1 micron, from 50 angstroms to 2500 angstroms, from 50 angstroms to 1000 angstroms, from 100 angstroms to 1000 angstroms, from 100 angstroms to 500 angstroms, from 100 angstroms to 200 angstroms, etc. To the resistor passivation layer is applied an amorphous thin metal protective layer 380 having a first layer 381 and a second layer 382. Any of the materials described herein that include a metalloid (Si, C, or B), a first and second metal of Groups IV, V, VI, VII, VIII, IX, and X, etc., can be selected for used for the first layer, as described herein. The second layer of the thin metal protective layer can be formed of an oxide layer, a nitride layer, or a combination thereof, as described herein.

Insulating materials that can be used for the electrical insulating layer 320, the conductor passivation layers 350, and the resistor passivation layer 370, or any other insulating layer can be SiO₂, SiN, Al₂O₃, HfO₂, ZrO₂, or undoped silicate glass, for example. The electrical insulating films or passivation layers, for example, can be formed by thermal oxidation of the resistor or conductors or deposition of an electrically insulating thin film. Also, it is noted that the resistor passivation layer and the conductor passivation layers 350 can be integrated as a single layer, or may remain as separate, adjacent layers. It is noted that many other types or positioning of layers can also be used as would be appreciated by one skilled in the art after considering the present disclosure.

It is noted that, as used in this specification and the appended claims, the singular forms “a,” “an,” and “the” include plural referents unless the context clearly dictates otherwise.

As used herein, “devoid of” refers to the absence of materials in quantities other than trace amounts, such as impurities.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 5 at % to about 90 at %” should be interpreted to include not only the explicitly recited values of about 5 at % to about 90 at %, but also include individual values and sub-ranges within the indicated range. Thus, included in this numerical range are individual values such as 6, 7.5, and 8 and sub-ranges such as from 5-75, from 7-80, and from 9-85, etc. This same principle applies to ranges reciting only one numerical value. Furthermore, such an interpretation should apply regardless of the breadth of the range or the characteristics being described.

### EXAMPLES

The following examples illustrate features of the disclosure that are presently known. Thus, these examples should not be considered as a limitation of the present technology, but are merely in place to teach how to make compositions of the present disclosure. As such, a representative number of compositions and their methods of manufacture are disclosed herein.

### Example 1—Oxide Film Formation

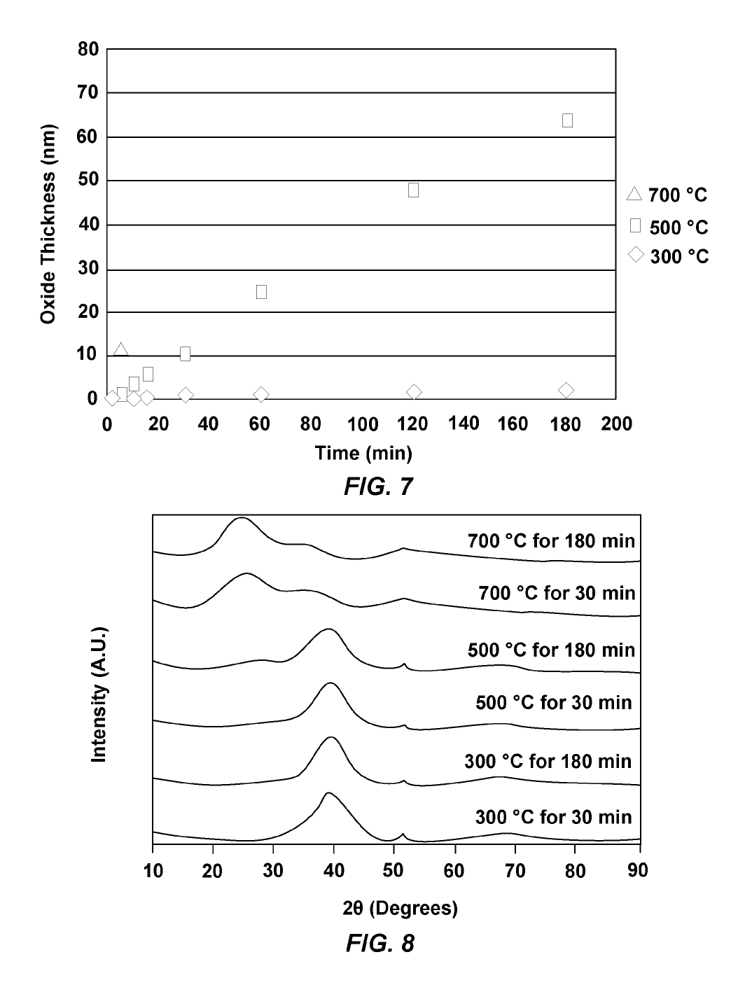

Various samples of a 30 at % tantalum, 30 at % tungsten, 40 at % silicon amorphous thin metal film or ally were prepared by DC sputter deposition onto silicon dioxide substrates at a throw distance of about 4 inches and a pressure of about 10 mTorr. The samples were placed into an oxidation furnace at various temperatures to determine the rate of oxide formation. As can be seen in FIG. 7, as the temperature of the furnace was increased, the rate of formation of the oxide layer also increased.

In one specific example, the oxide layer was approximately 15 nm to 17 nm thick after 15 minutes oxidation at 500° C. In another example, the amorphous thin metal film or alloy was oxidized at 700° C. and the oxide film thickness increased by more than 150 nm. Further, it was found that the oxide layers formed on the amorphous thin metal films were highly uniform. More specifically, the oxide layers had a thickness variance of less than 15% of the average thickness of the respective oxide layers, as determined by both ellipsometry and x-ray reflectometry (XRR)

### Example 2—Characterization of Amorphous Thin Film Stack

The samples described in Example 1 were further evaluated using x-ray diffraction to determine the effect of oxide formation on the amorphous structure of the underlying thin metal film or alloy. As can be seen in FIG. 8, the stacked x-ray diffraction patterns of the thin metal films illustrate that the various amorphous thin metal films remain amorphous under the oxidation conditions tested.

While the present technology has been described with reference to certain examples, those skilled in the art will appreciate that various modifications, changes, omissions, and substitutions can be made without departing from the spirit of the present technology. It is intended, therefore, that the present technology be limited only by the scope of the following claims.

What is claimed is:

1. An amorphous thin film stack, comprising:
a first layer of an amorphous thin metal film, comprising:
5 at % to 90 at % of a metalloid, wherein the metalloid is carbon, silicon, or boron,
5 at % to 90 at % of a first metal, wherein the first metal is titanium, vanadium, chromium, iron, cobalt, nickel, niobium, molybdenum, ruthenium, rhodium, palladium, tantalum, tungsten, osmium, iridium, or platinum, and
5 at % to 90 at % of a second metal, wherein the second metal is titanium, vanadium, chromium, iron, cobalt, nickel, niobium, molybdenum, ruthenium, rhodium, palladium, tantalum, tungsten, osmium, iridium, or platinum, wherein the second metal is different than the first metal,
wherein the metalloid, the first metal, and the second metal account for at least 70 at % of the amorphous thin metal film; and
a second layer formed on a surface of the first layer, the second layer being an oxide layer, a nitride layer, or a combination thereof, and the second layer having an average thickness of 10 angstroms to 200 microns and having a thickness variance no greater than 15% of the average thickness of the second layer.

2. The amorphous thin film stack of claim 1, wherein the first layer has an average thickness of from 10 angstroms to 100 microns.

3. The amorphous thin film stack of claim 1, wherein the second layer has an average thickness of from 20 angstroms to 100 microns.

4. The amorphous thin film stack of claim 1, wherein the first layer further comprises from 0.1 at % to 15 at % of a dopant of nitrogen, oxygen, or mixture thereof.

5. The amorphous thin film stack of claim 1, wherein the first layer further comprises from 5 at % to 85 at % of a third metal, the third metal being titanium, vanadium, chromium, iron, cobalt, nickel, niobium, molybdenum, ruthenium, rhodium, palladium, tantalum, tungsten, osmium, iridium, or platinum, wherein the third metal is different than the first metal and the second metal.

6. The amorphous thin film stack of claim 5, wherein the first metal, the second metal, the third metal, or a combination thereof is a refractory metal, the refractory metal being selected from titanium, vanadium, chromium, niobium, molybdenum, ruthenium, rhodium, tantalum, tungsten, osmium, or iridium.

7. The amorphous thin film stack of claim 1, wherein the second layer is an oxide layer.

8. The amorphous thin film stack of claim 1, wherein the second layer is a nitride layer.

9. A method of manufacturing an amorphous thin film stack, comprising:
depositing a first layer of an amorphous thin metal film to a substrate, the amorphous thin metal film, comprising:
5 at % to 90 at % of a metalloid, wherein the metalloid is carbon, silicon, or boron,
5 at % to 90 at % of a first metal, wherein the first metal is titanium, vanadium, chromium, iron, cobalt, nickel, zirconium, niobium, molybdenum, ruthenium, rhodium, palladium, hafnium, tantalum, tungsten, osmium, iridium, or platinum, and
5 at % to 90 at % of a second metal, wherein the second metal is titanium, vanadium, chromium, iron, cobalt, nickel, zirconium, niobium, molybdenum, ruthenium, rhodium, palladium, hafnium, tantalum, tungsten, osmium, iridium, or platinum, and wherein the second metal is different than the first metal; and
forming a second layer on a surface of the first layer, the second layer being an oxide layer, a nitride layer, or a combination thereof, and the second layer having an average thickness of 20 angstroms to 200 microns and having a thickness variance no greater than 15% of the average thickness of the second layer.

10. The method of claim 9, wherein the step of depositing the first layer includes sputtering.

11. The method of claim 10, wherein the step of forming the second layer includes placing the amorphous thin metal film in a furnace and heating at a temperature of from 200° C. to 1000° C.

12. The method of claim 10, wherein the step of forming the second layer includes exposing the surface of the first layer to an oxygen plasma to form the oxide layer.

13. A MEMS device, comprising:
a substrate;
a first layer of an amorphous thin metal film applied to the substrate, the amorphous thin metal film, comprising:
5 at % to 90 at % of a metalloid, wherein the metalloid is carbon, silicon, or boron;
5 at % to 90 at % of a first metal, wherein the first metal is titanium, vanadium, chromium, iron, cobalt, nickel, zirconium, niobium, molybdenum, ruthenium, rhodium, palladium, hafnium, tantalum, tungsten, osmium, iridium, or platinum; and
5 at % to 90 at % of second metal, wherein the second metal is titanium, vanadium, chromium, iron, cobalt, nickel, zirconium, niobium, molybdenum, ruthenium, rhodium, palladium, hafnium, tantalum, tungsten, osmium, iridium, or platinum, wherein the second metal is different than the first metal, and
wherein the metalloid, the first metal, and the second metal account for at least 70 at % of the amorphous thin metal film; and
a second layer formed on a surface of the amorphous thin metal film, the second layer being an oxide layer, a nitride layer, or a combination thereof, and the second layer having an average thickness of 20 angstroms to 200 microns and a having thickness variance no greater than 15% of the average thickness of the second layer.

14. The MEMS device of claim 13, wherein the first layer has an average thickness of from 10 angstroms to 2 microns.

15. The MEMS device of claim 13, wherein the second layer has an average thickness of from 100 angstroms to 4 microns.
